(19) United States
(12) Patent Application Publication
(10) Pub. No.: US 2017/0352573 A1
(43) Pub. Date: Dec. 7, 2017

(54) SUBSTRATE PROCESSING APPARATUS

(71) Applicant: EBARA CORPORATION, Tokyo (JP)

(72) Inventors: Zhongxin WEN, Tokyo (JP); Toru MARUYAMA, Tokyo (JP); Nobuyuki TAKAHASHI, Tokyo (JP); Suguru SAKUGAWA, Tokyo (JP); Yoichi SHIOKAWA, Tokyo (JP); Keita YAGI, Tokyo (JP); Itsuki KOBATA, Tokyo (JP); Tomohiko TAKEUCHI, Tokyo (JP)

(21) Appl. No.: 15/615,475

(22) Filed: Jun. 6, 2017

(30) Foreign Application Priority Data
Jun. 7, 2016 (JP) 2016-113501

(51) Int. Cl. H01L 21/687; G03F 7/20; B24B 41/06; H01L 21/683; B24B 37/04

(52) U.S. Cl. CPC H01L 21/68757; H01L 21/68714; H01L 21/6838; B24B 37/04; B24B 41/068; G03F 7/70691

(57) ABSTRACT

It is an object of the present invention to provide a high-flatness substrate holding table. According to a first aspect, a substrate processing apparatus is provided, and such a substrate processing apparatus includes a table for holding a substrate, a resin film attached to a top surface of the table and a heater provided inside the table, and the top surface of the table is formed of ceramics, the top surface of the table includes an opening connectable to a vacuum source, the resin film is formed of polyimide, and a through hole is formed at a position corresponding to the opening of the table when attached to the top surface of the table.

### CROSS-REFERENCE TO RELATED APPLICATION

This application is based upon and claims the benefit of priority of the prior Japanese Patent Application No. 2016-113501, filed on Jun. 7, 2016, the entire content of which is incorporated herein by reference.

### BACKGROUND

The present application relates to a substrate processing apparatus.

Chemical mechanical polishing (CMP) apparatuses are known as apparatuses for polishing substrate surfaces in manufacturing semiconductor devices. In a CMP apparatus, a polishing pad is stuck to a top surface of a polishing table to form a polishing surface. This CMP apparatus pushes a surface to be polished of a substrate held by a top ring against the polishing surface and rotates the polishing table and the top ring while supplying slurry as a polishing liquid to the polishing surface. This causes the polishing surface and the surface to be polished to relatively move slidably, and the surface to be polished is thereby polished.

Regarding flattening techniques including CMP, there are a wide variety of materials to be polished and requirements for polishing performance (e.g., flatness, polishing damage, and further productivity) are becoming stricter in recent years. With an introduction of more refined semiconductor devices, there is a growing demand for polishing performance and cleanliness in CMP apparatuses.

Under such circumferences, substrates may be processed using polishing pads smaller in size than the substrates to be processed in the CMP apparatuses (e.g., U.S. Pat. No. 6,561,881). Generally, a polishing pad smaller in size than a substrate to be processed can flatten locally generated unevenness on a substrate, polish only specific parts of the substrate or adjust the amount of polishing in accordance with the position of the substrate, and provides excellent controllability.

On the other hand, new flattening methods are also being proposed, and a catalyst referred etching (hereinafter, referred to as “CARE”) method is one such example. In the presence of a processing liquid, the CARE method generates a seed of reaction with a surface to be polished from within the processing liquid only in the vicinity of a catalyst material, causes the catalyst material and the surface to be polished to come closer to or come into contact with each other, and can thereby selectively make etching reaction occur on the surface to be polished (e.g., WO2015/159973, pamphlet). For example, with an uneven surface to be polished, selective etching of convex parts is made possible by causing the convex parts and the catalyst material to come closer to or come into contact with each other and it is possible to further flatten the surface to be polished.

Furthermore, a polishing speed and an etching speed of a substrate depend on a temperature of a region where the surface of a substrate and a pad come into contact with each other. Therefore, in order to flatten the substrate accurately, it is desirable to control the temperature of the region where the surface of the substrate and the pad come into contact with each other.

In a polishing apparatus that polishes a substrate surface from above, the substrate is held from below by means of vacuum suction using a rotatable table. Conventionally, a table that holds a substrate has a groove pattern for suctioning formed on the surface of a flat table, the substrate is directly placed on the table and vacuum-suctioned. Therefore, a non-flat part of the table may affect the substrate placed thereon and affect flatness of the surface of the polished substrate. For example, when the substrate is vacuum-suctioned to the table, the substrate does not come into contact with the non-flat part of the table. For this reason, a gap may be produced between the table and the substrate, air may leak from the gap and the suction rate of the substrate may decrease. Furthermore, since the material used for the table is generally a high hardness material, the reverse side of the substrate contacting the table is susceptible to damage. On the other hand, to reduce damage to the reverse side of the substrate, the table may be made of resin which has relatively low hardness, but a resin-made table generally has poor flatness.

With the CARE method and CMP, a processing speed (polishing speed, etching speed) of a wafer Wf generally depends on a temperature of a substrate surface to be processed. Therefore, to control the temperature of the substrate surface to be processed, a temperature-adjusted chemical solution or pure water may be supplied to the substrate surface so as to adjust the surface temperature of the substrate through heat exchange between the liquid and the substrate. However, since the temperature-adjusted chemical solution or pure water is supplied to the substrate surface through a channel, the temperature of the liquid reaching the substrate surface may be different from a set temperature depending on its environment. Furthermore, since the chemical solution or pure water remains in the channel, even when the set temperature of the liquid is changed, the temperature of the liquid supplied to the substrate does not immediately change. Furthermore, the temperature of the substrate surface may exceed the set temperature (overshoot) or fall below the set temperature (undershoot) due to heat accumulation of the table. Furthermore, the closer to a supply port of the temperature-adjusted liquid a portion of the substrate is, the greater the effect of temperature adjustment becomes and the less likely it is for a temperature distribution of the substrate surface to become uniform. Moreover, it is not possible to control the temperature distribution of the substrate surface and it is difficult to control the substrate temperature.

It is an object of the present invention to mitigate or solve at least some of the above-described problems.

### SUMMARY

According to a first aspect, a substrate processing apparatus is provided. The substrate processing apparatus includes a table for holding a substrate, a resin film attached to a top surface of the table and a heater provided inside the table, in which the top surface of the table is formed of ceramics, the top surface of the table defines an opening connectable to a vacuum source, the resin film is formed of polyimide, and the resin film define a through hole at a position corresponding to the opening of the table when the resin film is attached to the top surface of the table. According to such an aspect, it is possible to form a flat table using a ceramic, high hardness material, and support the substrate via a relatively less hard resin film to thereby reduce a possibility of damaging the substrate while maintaining high flatness of the top surface of the table. Furthermore, the resin-made film is less hard than the table and deformable to a certain degree, and it is thereby possible to improve a state of contact between the table and the substrate and suppress air leakage during vacuum suctioning. It is also possible to control the temperature of the substrate surface to be processed and control the substrate processing speed using a heater. It is also possible to control hardness of the resin-made film using the heater.

According to a second aspect, the substrate processing apparatus according to the first aspect includes a temperature sensor to measure a surface temperature of the substrate held on the table. According to such an aspect, it is possible to measure the surface temperature of the substrate using the temperature sensor, and thereby control the surface temperature of the substrate so that the substrate surface has an optimum temperature.

According to a third aspect, the substrate processing apparatus according to the second aspect includes a controller that can communicate with the temperature sensor and the heater, and the controller is configured so as to control the heater based on the temperature measured by the temperature sensor. According to such an aspect, the controller can perform control so that the substrate surface has a desired temperature.

According to a fourth aspect, in the substrate processing apparatus according to the third aspect, the table includes a plurality of regions, the heater includes a plurality of heaters arranged at positions corresponding to the plurality of regions of the table and the controller is configured so as to control the plurality of heaters independently of each other. According to such an aspect, it is possible to form a desired temperature distribution on the substrate surface and control a substrate processing speed for each region.

### BRIEF DESCRIPTION OF THE DRAWINGS

FIG. 1 is schematic plan view of a substrate processing apparatus of a substrate processing system as an embodiment;

FIG. 2 is a schematic side view of the substrate processing apparatus according to the embodiment; and

FIG. 3 is a schematic side view of a substrate processing apparatus according to another embodiment.

### DETAILED DESCRIPTION

Hereinafter, embodiments of a substrate processing apparatus according to the present invention will be described with reference to the accompanying drawings. In the attached drawings, identical or similar elements are assigned identical or similar reference numerals, and duplicate description relating to the identical or similar elements in the respective embodiments will be omitted. Features shown in each respective embodiment are also applicable to the other embodiments unless they are inconsistent with each other.

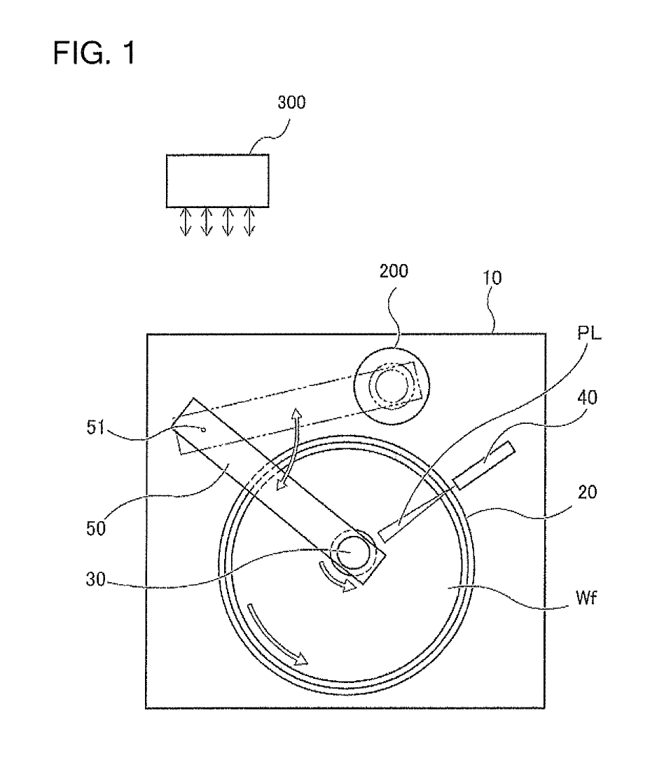

FIG. 1 is a schematic plan view of a substrate processing apparatus 10 of a substrate processing system as an embodiment. The substrate processing apparatus 10 is an apparatus that performs etching processing on a semiconductor material (region to be processed) on a substrate using a CARE method. Alternatively, the substrate processing apparatus 10 can also be configured as a CMP apparatus using a pad smaller in size than the substrate. The substrate processing system is provided with the substrate processing apparatus 10, a substrate cleaning section (not shown) configured to clean the substrate and a substrate conveying section (not shown) that conveys the substrate. The substrate processing system may also be provided with a substrate drying section (not shown) as required. The substrate conveying section is configured to be able to convey a wet-state substrate and a dry-state substrate separately. Furthermore, depending on the type of a semiconductor material, processing through CMP may be performed using a polishing pad greater in size than a conventional substrate to be processed before or after the processing by the substrate processing apparatus 10, and therefore the substrate processing system may be provided with a CMP apparatus further including a large-diameter polishing pad. The substrate processing system may further include a film formation apparatus such as a chemical vapor deposition (CVD) apparatus, a sputtering apparatus, a plating apparatus and a coater apparatus. In the present embodiment, the substrate processing apparatus 10 is configured as a unit separate from the CMP apparatus. Since the substrate cleaning section, the substrate conveying section and the CMP apparatus are known techniques, illustration and description thereof are omitted hereinafter.

The substrate processing apparatus 10 is provided with a table 20 to hold a substrate, a head 30 provided with a pad that holds a catalyst, a processing liquid supply section 40, a swing arm 50, a conditioning section 200 and a control section 300. The table 20 is provided with a substrate holding surface and configured to hold a wafer Wf as a kind of substrate on the substrate holding surface. In the present embodiment, the table 20 holds the wafer Wf such that a surface to be processed of the wafer Wf faces up. In the present embodiment, the table 20 is provided with a vacuum suction mechanism including a vacuum suction plate to vacuum-suction the reverse side (surface opposite to the surface to be processed) of the wafer Wf as a mechanism to hold the wafer Wf. As a vacuum suction scheme, either one of the two schemes may be used: a point suction scheme using a suction plate including a plurality of suction holes connected to a vacuum line on the suction surface and a surface suction scheme including (e.g., concentric) grooves on the suction surface to suction the wafer through connection holes to a vacuum line provided in the grooves. However, an arbitrary publicly known mechanism can be used as the mechanism for holding the wafer Wf, and for example, a clamp mechanism that clamps the front side and the reverse side of the wafer Wf on at least one of peripheral edges of the wafer Wf or a roller chuck mechanism that holds a side face of the wafer Wf on at least one of peripheral edges of the wafer Wf may be used. Such a table 20 is configured so as to be rotatable using a drive section motor or an actuator (not shown).

The head 30 of the embodiment shown in FIG. 1 is configured to hold a catalyst at a bottom end thereof. In the present embodiment, the size of the head 30 is smaller than that of the wafer Wf. That is, when an image of the head 30 is projected toward the wafer Wf, the projected area of the head 30 is smaller than the area of the wafer Wf. Furthermore, the head 30 is configured to be rotatable by a drive section, that is, an actuator (not shown). Furthermore, a motor or an air cylinder (not shown) is provided inside the swing arm 50 to move the head 30 upward or downward with respect to the wafer Wf so as to bring the catalyst of the head 30 into sliding contact with the wafer Wf.

The processing liquid supply section 40 is configured to supply a processing liquid PL to the surface of the wafer Wf. Here, the number of processing liquid supply sections 40 is one in FIG. 1, but a plurality of processing liquid supply sections 40 may be arranged, and in that case, different processing liquids may be supplied from the respective processing liquid supply sections. When the surface of the wafer Wf is cleaned in the substrate processing apparatus 10 after etching processing, a cleaning chemical solution or water may be supplied from the processing liquid supply section 40. As another embodiment, the processing liquid supply section 40 may be configured to supply the processing liquid PL from the surface of the head 30 to the surface of the wafer Wf after passing through the swing arm 50 and the head 30. As an embodiment, the processing liquid supply section 40 may be provided with a temperature adjustment unit for adjusting a temperature of the processing liquid so as to be able to control the temperature of the liquid supplied to the wafer Wf.

As shown in FIG. 1, the swing arm 50 is configured to be swingable around a center of rotation 51 by a drive section, that is, an actuator (not shown). Furthermore, the head 30 is configured to be movable upward or downward and able to push the head 30 against the wafer Wf. The head 30 is attached to a distal end of the swing arm 50 (end portion opposite to the center of rotation 51).

In the embodiment shown in FIG. 1, the control section 300 can be constructed of a general-purpose computer or a dedicated computer provided with, for example, a CPU, a storage apparatus such as a memory and an input/output apparatus. The control section 300 is connected to various components in the substrate processing apparatus 10, stores programs to control their operations and can control operation of the entire substrate processing apparatus 10.

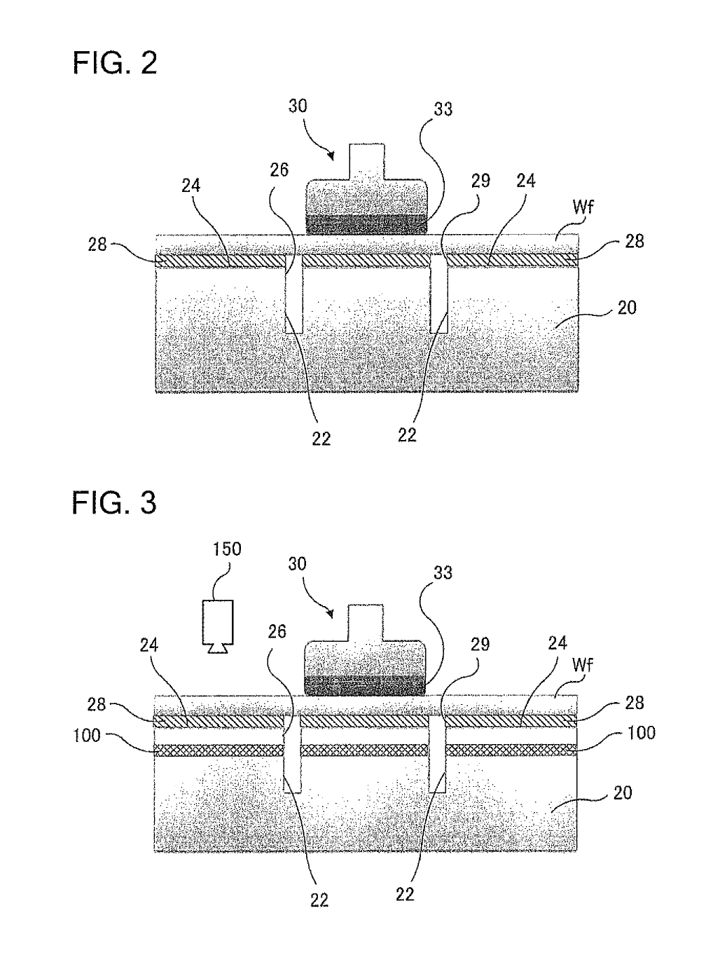

FIG. 2 is a schematic side view of the substrate processing apparatus 10 according to the embodiment. FIG. 2 shows a state in which the head 30 is in contact with the wafer Wf. Note that in FIG. 2, the mechanism for moving the head 30 upward or downward, the swing arm 50 and the processing liquid supply section 40 are omitted. The head 30 is provided with a pad 33 that comes into contact with the wafer Wf to process the wafer Wf. The pad 33 can be a pad to which a CARE catalyst is applied. Alternatively, as another embodiment, the pad can also be a pad for CMP.

As described above, the table 20 is configured to be rotatable. As shown in FIG. 2, the table 20 includes a passage 22 connected to a vacuum source (not shown). The passage 22 communicates with an opening 26 provided on a top surface 24 of the table 20. The table 20 as a whole or at least the top surface is formed of ceramics. Ceramics is generally a high hardness material which allows a table whose top surface has a high degree of flatness compared to a material having a relatively small degree of hardness such as resin to be formed. Moreover, ceramics generally has excellent heat-resistance and is less deformed by heat. In the embodiment shown in FIG. 2, a resin film 28 is placed on the top surface 24 of the table 20. As shown in FIG. 2, the resin film 28 is provided with a through hole 29 at a position corresponding to the opening 26 of the table 20 when placed on the top surface 24 of the table 20. The resin film 28 can be adhered to the top surface 24 of the table 20 using, for example, a double-sided tape or may be adhered to the top surface 24 of the table 20 using an adhesive. The resin film 28 can be formed of resin having excellent heat-resistance such as polyimide. Furthermore, the resin film 28 may also be formed of polyether ether ketone (PEEK), polyethylene terephthalate (PET), polyvinyl chloride (PVC) or the like. The resin film 28 preferably has a thickness of approximately 30 μm to approximately 500 μm to mitigate hardness of the table surface while maintaining flatness of the table.

As described above, the ceramic table 20 can attain a table whose top surface 24 has a high degree of flatness, but since it has high hardness, when the wafer Wf is directly placed on the table 20, the wafer Wf may be damaged. In the embodiment in FIG. 2, since the resin film 28 less hard than ceramics is placed on the top surface 24 of the table 20, it is possible to reduce a possibility of damaging the wafer Wf while maintaining high flatness of the top surface of the table 20.

FIG. 3 is a schematic side view of the substrate processing apparatus 10 according to another embodiment. The table 20 of the substrate processing apparatus 10 according to the embodiment shown in FIG. 3 is provided with a heater 100 at a position below the top surface 24. The heater 100 can be placed over substantially the whole surface of the table 20 except the portions of the passages 22 in the table 20. The heater 100 is configured so as to be controlled by the control section 300. The heater 100 may also be divided into a plurality of regions in the table 20 and arranged, and configured to be separately controllable for each divided region. It is thereby possible to control a temperature distribution on the surface of the wafer Wf. The heater 100 can be formed of a common heating wire. For example, when the ceramic table 20 is manufactured, by embedding the heating wire therein, it is possible to manufacture the table 20 with the heater 100 embedded therein.

In the embodiment shown in FIG. 3, the substrate processing apparatus 10 includes a temperature sensor 150. The temperature sensor 150 can be, for example, a non-contact type temperature sensor such as a thermography or infrared sensor. The temperature sensor 150 is placed so as to be able to measure a temperature of the surface of the wafer Wf. For example, the temperature sensor 150 may be held by a moving mechanism (not shown) and configured to be able to scan the surface of the wafer Wf. The temperature sensor 150 is connected to the control section 300. The control section 300 controls the heater 100 based on temperature information on the surface of the wafer Wf received from the temperature sensor 150 during processing on the wafer Wf.

According to the CARE method or CMP, the processing speed of the wafer Wf (polishing speed, etching speed) depends on the temperature of the surface of the wafer Wf. In the embodiment shown in FIG. 3, it is possible to control the temperature of the surface of the wafer Wf using the heater 100 placed in the table 20. In such an embodiment, it is possible to adjust the temperature of the surface of the wafer Wf more speedily than the case with temperature control of the surface of the wafer Wf through the aforementioned processing liquid. Furthermore, the whole surface of the table 20 can be heated uniformly using the heater 100, it is thereby possible to uniformly heat the surface of the wafer Wf. Furthermore, it may be possible to divide the surface of the table 20 into a plurality of regions, arrange the heater 100 for each divided region and perform temperature control independently for each divided region. By performing temperature control independently for each divided region, it is possible to change the processing speed (polishing speed, etching speed) for each divided region and control the processing on the wafer Wf more accurately. Since the temperature sensor 150 directly measures the temperature of the surface of the wafer Wf, it is possible to measure the temperature of the surface of the wafer Wf accurately compared to cases of measuring the temperature in the table 20 or the temperature of the processing liquid. Furthermore, in the embodiment shown in FIG. 3, since the resin film 28 placed on the top surface 24 of the table 20 is also heated by the heater 100, it is possible to control hardness of the resin film 28.

### DESCRIPTION OF THE NUMERALS

10 . . . Substrate processing apparatus
20 . . . Table
22 . . . Passage
24 . . . Top surface
26 . . . Opening
28 . . . Resin film
29 . . . Through hole
30 . . . Head
33 . . . Pad
40 . . . Processing liquid supply section
50 . . . Swing arm
51 . . . Center of rotation
100 . . . Heater
150 . . . Temperature sensor
200 . . . Conditioning section
300 . . . Control section
Wf . . . Wafer
PL . . . Processing liquid

What is claimed is:

1. A substrate processing apparatus comprising:
a table for holding a substrate;
a resin film attached to a top surface of the table; and
a heater provided inside the table,
wherein the top surface of the table is formed of ceramics, the top surface of the table defines an opening connectable to a vacuum source,
the resin film is formed of polyimide, and the resin film define a through hole at a position corresponding to the opening of the table when the resin film is attached to the top surface of the table.

2. The substrate processing apparatus according to claim 1, further comprising a temperature sensor to measure a surface temperature of the substrate held on the table.

3. The substrate processing apparatus according to claim 2, further comprising a controller that can communicate with the temperature sensor and the heater,
wherein the controller is configured to control the heater based on the temperature measured by the temperature sensor.

4. The substrate processing apparatus according claim 3,
wherein the table comprises a plurality of regions,
the heater comprises a plurality of heaters arranged at positions corresponding to the plurality of regions, and
the controller is configured so as to control the plurality of heaters independently of each other.
